(19) United States
(12) Patent Application Publication
(10) Pub. No.: US 2005/0285658 A1
(43) Pub. Date: Dec. 29, 2005

(54) Level shifter with reduced duty cycle variation

(76) Inventors: Kyle C. Schulmeyer, Austin, TX (US); Lloyd P. Matthews, Buda, TX (US); Bernard J. Pappert, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/880,132

(22) Filed: Jun. 29, 2004

(51) Int. Cl. H03F 1/26

(52) U.S. Cl. 327/333

(57) ABSTRACT

A voltage level shifting circuit (10) transitions an input signal at a first voltage to a second voltage higher than the first voltage. A cross-coupled latch provides the second voltage. Cascode configured transistors (16, 26) are connected in series with input transistors (18, 28) that receive the first voltage in complementary form. Capacitive devices (34, 40) are connected between the first voltage and gates of the cascode configured transistors for allowing independent small signal variations to occur on the gates of the cascode configured transistors for better control of duty cycle and rise and fall time matching of the level shifting circuit. Isolation devices (32, 38) permit independent modification of small signal voltages to occur on the gates of the cascode configured transistors.

### FIELD OF THE INVENTION

This invention relates to electronic circuits, and more particularly to electronic circuitry for shifting a voltage level of a signal.

### BACKGROUND OF THE INVENTION

Integrated circuits typically have peripheral or input/output (I/O) circuitry and internal core circuitry. The cores of the integrated circuit perform various processing-specific functions and are desired to operate as fast as possible with minimal power consumption. As a result, power supply voltages that are used to power the core circuitry have been getting smaller with the enhancement of semiconductor processing. The I/O circuitry however functions to provide circuit drive strength to drive or provide signals from the core to external sources at a specified signal power. The I/O circuitry also is frequently required to interface with various interface standards. Such interface standards have not been getting smaller in voltage value to the same degree that core circuitry has been. As a result, there is an increasing differential in power supply voltage values and signal strength between the I/O circuitry and the core circuitry. To communicate between the I/O circuitry and the core circuitry, a voltage translation is required to either increase or reduce voltage levels.

An example of a voltage level shifter is provided in U.S. Pat. No. 6,614,283 by Wright et al. entitled “Voltage Level Shifter” for shifting from a core voltage up to an output voltage for use by I/O circuitry. The voltage level shifter uses N-channel transistors that are biased by an input voltage. When each of these N-channel transistors is in an off-state, the drain of the N-channel transistor that is nonconductive will drift toward the I/O supply voltage. Because the gate oxides of these N-channel transistors are thin relative to transistor oxides in the peripheral circuitry, a floating drain voltage causes transistor reliability problems such as hot carrier injection (HCI), an excessive gate-to-drain voltage, and other undesired operation.

Another example of a voltage level shifter is provided in an EPO patent EP 0 608 489 B 1 by Hardee et al. Cascode transistors that function to voltage limit are biased by the low voltage core supply. Therefore, operation of this level shifter will not have optimal speed. Transistors may have the gate width modified to change operating parameters such as speed of device turn-on. However, such sizing modifications result in more of a duty cycle skew as the core supply voltage lowers in value.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the following drawings:

FIG. 1 represents in schematic form a voltage level shifter in accordance with one form of the present invention; and

FIG. 2 represents in schematic form a voltage level shifter in accordance with another form of the present invention.

### DETAILED DESCRIPTION

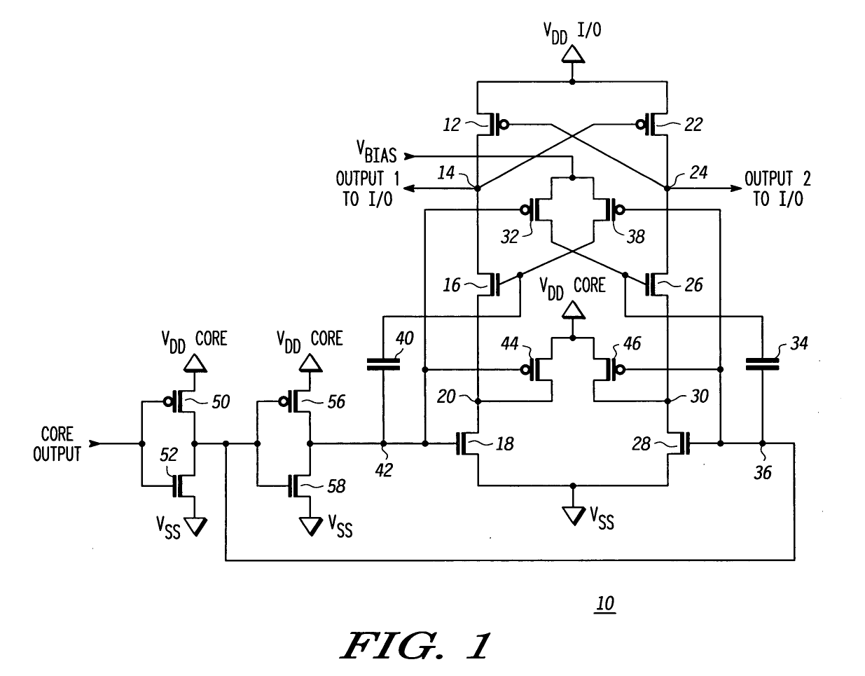

FIG. 1 illustrates a voltage level shifter 10 for shifting a voltage from core circuitry (not shown) up to a higher value for use by I/O circuitry (not shown). A P-channel transistor 12 has a source connected to an I/O power supply labeled V_{DD}I/O. A drain of transistor 12 is connected at a node 14 to a drain of an N-channel transistor 16. A gate of transistor 12 is connected to a node 24. In the illustrated form transistors in the I/O circuitry have gate oxide thickness that are much greater than transistors in the core. The transistors with large gate oxide thickness are referred to herein as ‘high voltage’ transistors and the transistors with smaller gate oxide thickness are referred to herein as ‘low voltage’ transistors. Transistor 16 has a source connected to a drain of an N-channel transistor 18 at a node 20. A source of transistor 18 is connected to a power supply voltage terminal labeled V_{SS}. The V_{SS} supply is typically an earth ground potential, but regardless of what reference voltage is selected V_{SS} has the same value within the I/O circuitry and the core circuitry. A P-channel transistor 22 has a source connected to the VDDI/O power supply. A gate of transistor 22 is connected to node 14 and to the drain of transistor 12. A drain of transistor 22 is connected to a drain of an N-channel transistor at node 24. Node 14 provides an first output to the I/O circuitry, and node 24 provides a second output to the I/O circuitry. The source of transistor 26 is connected to a drain of an N-channel transistor 28 at a node 30. A source of transistor 28 is connected to V_{SS}. A P-channel transistor 32 has a source connected to a bias voltage labeled V_{BIAS}. A gate of transistor 32 is connected to a gate of transistor 18 at a node 42. A drain of transistor 32 is connected to a gate of transistor 26 and to a first electrode of a capacitor 34.

A second electrode of capacitor 34 is connected to a node 36. A P-channel transistor 38 has a source connected to the V_{BIAS} bias voltage. A gate of transistor 38 is connected to node 36. A drain of transistor 38 is connected to a gate of transistor and to a first electrode of a capacitor 40. A second electrode of capacitor 40 is connected to a gate of transistor 18 at a node 42. A P-channel transistor 44 has a source connected to a core power supply voltage labeled “V_{DD} Core”. A gate of transistor 44 is connected to a gate of transistor 32 and to the gate of transistor 18. A drain of transistor 44 is connected to the drain of transistor 18 at node 20. A P-channel transistor 46 has a source connected to the core power supply voltage V_{DD} Core. A gate of transistor 46 is connected to a gate of transistor 28 and to the gate of transistor 38. A drain of transistor 46 is connected to the drain of transistor 28 at node 30. The Core Output is connected to the gates of a P-channel transistor 50 and an N-channel transistor 52 that are connected together. A source of transistor 50 is connected to the V_{DD} Core. A drain of transistor 50 is connected to a drain of transistor 52 at node 36. The source of transistor 52 is connected to the supply voltage terminal V_{SS}. A P-channel transistor 56 has a source connected to the V_{DD} Core. A gate of transistor 56 is connected to a gate of an N-channel transistor 58 at node 36. A drain of transistor 56 is connected to a drain of transistor 58 at node 42. A source of transistor 58 is connected to the supply voltage terminal VSS. In the illustrated form, transistors 12, 16, 22, 26, 32, 38, 44 and 46 are high voltage transistors. It should be understood that in another form transistor 44 and transistor 46 may be implemented as low voltage transistors with thinner gate oxides because no voltage greater than the V_{DD} Core voltage is presented to any portion of these two transistors. In particular, the sources of transistors 44 and 46 are connected to the V_{DD} Core supply voltage and the drains of transistors 44 and 46 are removed from the V_{DD}I/O supply voltage by at least two transistor voltage drops. In the illustrated form, transistors 18, 28, 50, 52, 56 and 58 are low voltage transistors.

In operation, voltage level shifter 10 receives a voltage, labeled Core Output, from core circuitry (not shown) and shifts or translates the voltage level of the Core Output, from a relatively low value, such as 0.7 to 1.7 volts, for example, to a higher voltage for use by I/O circuitry (not shown). The I/O circuitry may operate at voltages such as 2.5 to 4.0 volts, for example. It should be well understood that these voltage values are provided by way of example only and other voltages outside of the ranges provided may be implemented.

Generally, voltage level shifter 10 has a cross-coupled latch formed by transistors 12 and 22. The cross-coupled latch is set and reset by transistors 18 and 28 that are respectively connected in series with transistors 12 and 22 by intervening transistors 16 and 26, respectively. Transistors 16 and 26 function as cascode configured devices for transistors 18 and 28, respectively. Transistors 32 and 38 function as switches or switching devices that selectively switch the V_{BIAS} voltage to the gates of the cascode configured transistors. Transistors 44 and 46 are voltage clamping transistors as will be explained below. Capacitors 34 and 40 are charge storage devices that selectively pull charge from the gates of the cascode devices as will be explained below.

When the Core Output voltage is a logic low value (i.e. around zero volts), transistors 50 and 52 function as an inverter to provide a logic high value at node 36. Transistors 56 and 58 also function as an inverter and therefore the voltage at node 42 is a logic low value. A bias voltage, V_{BIAS}, assumes a value that is greater than the value of V_{DD}Core. The V_{BIAS} voltage is derived from the V_{DD}I/O supply voltage. In one form the V_{BIAS} voltage is one transistor threshold greater than V_{DD}Core. Since node 42 is a logic low value and node 36 is a logic high value, each of transistor 32 and transistor 38 weakly pass the V_{BIAS} bias voltage to the gate of transistor 26 and transistor 16, respectively. Since node 42 is a logic low value, the gate of transistor 26 is connected to the V_{BIAS} voltage through a low impedance formed by transistor 32. With the logic high value at node 36, transistor 38 is biased to assume a quasi-high impedance state because of sub-threshold operation. Since the gate of transistor 18 is a logic low value, transistor 18 is nonconductive. Transistor 28 is conductive and begins pulling node 30 to a logic low or V_{SS} value. At the same time that transistor 32 is turning on in response to the voltage at node 42, transistor 32 is further turning on transistor 26. With the logic high value at node 36, charge is being pushed onto the second electrode of capacitor 34 which further assists in turning on transistor 26. Since node 36 is at a high value, transistor 28 is pulling node 30 low which in turn pulls node 24 (the Output to the I/O circuitry) low.

Similarly, with node 36 being high, transistor 38 enters a high impedance state although not being fully turned off. With node 42 going low, and alternatively node 36 being high, the gate of transistor 16 is pulled low by capacitor 40 which puts transistor 16 in a low conductance state. Transistor 16 however is not fully turned off. With this biasing of transistor 16, transistor 12, which is turned on when node 24 is low, can pull node 14 to a higher level in a faster amount of time than would otherwise be possible if transistors 16, 44 and 18 were influencing node 14.

It should further be noted that when node 42 assume a logic low value, transistor 44 is made conductive. Transistors 44 and 46 are weak P-channel devices. The conduction of transistor 44 functions to clamp node 20 near the value of V_{DD}Core. Similarly, when node 36 assumes a logic low value, transistor 46 is made conductive. The conduction of transistor 46 functions to clamp node 30 near the value of V_{DD}Core. By clamping node 20 near the value of V_{DD}Core, damage to transistor 18 is prevented because transistor 18 is a low voltage transistor which can be damaged by any drain-to-source voltage and drain-to-gate voltage above the V_{DD}Core voltage. Similarly, by clamping node 30 near the value of V_{DD}Core, damage to transistor 28 is prevented because transistor 28 is also a low voltage transistor. While transistor 44 and transistor 46 are each sized to respectively actively limit the voltage at node 20 and node 30 at near V_{DD}Core when appropriate, the clamp voltage level can be adjusted for different technologies.

It should be noted that transistors 18 and 28 and the inverters formed by transistors 50, 52, 54 and 56 are formed of low voltage transistors. The purpose of using low voltage transistors for transistors 18 and 28 is because if high voltage transistors were used, the turn-on time of the high voltage transistors caused by the lower value of V_{DD}Core would degrade circuit performance. Also, isolation between V_{BIAS} and the gates of transistors 16 and 26 allows capacitors 40 and 34 to modify the voltages on the gates of transistors 16 and 26 as a function of the logic values at nodes 42 and 36.

Now assume an operating condition where the Core Output voltage is a logic high value. When the Core Output voltage is a logic high value (i.e. around one volt or less), transistors 50 and 52 again function as an inverter to provide a logic low value at node 36. Transistors 56 and 58 again function as an inverter and therefore the voltage at node 42 is a logic high value. Bias voltage, V_{BIAS}, assumes a value that is greater than the value of V_{DD}Core. The V_{BIAS} voltage is derived from the V_{DD}I/O supply voltage. In one form the V_{BIAS} voltage is one transistor threshold greater than V_{DD}Core. Since node 42 is a logic high value and node 36 is a logic low value, each of transistor 32 and transistor 38 weakly pass the V_{BIAS} bias voltage to the gate of transistor 26 and transistor 16, respectively. Since node 36 is a logic low value, the gate of transistor 16 is connected to the V_{BIAS} voltage through a low impedance formed by transistor 38. With the logic high value at node 42, transistor 32 is biased to assume a quasi-high impedance state because of sub-threshold operation. Since the gate of transistor 18 is a logic high value, transistor 18 is conductive. Transistor 28 is nonconductive. Transistor 18 begins pulling node 20 to a logic low or V_{SS} value. At the same time that transistor 38 is turning on in response to the voltage at node 36, transistor 38 is further turning on transistor 16. With the logic high value at node 42, charge is being pushed onto the second electrode of capacitor 40 which further assists in turning on transistor 16. Since node 42 is at a high value, transistor 18 is pulling node 20 low which in turn pulls node 14 (the Output to the I/O circuitry) low. Node 14 and node 24 are in complementary logic form to provide a high output voltage that can be further used depending upon which logic state is desired.

Similarly, with node 42 being high, transistor 32 enters a high impedance state although not being fully turned off. With node 36 going low, and alternatively node 42 being high, the gate of transistor 26 is pulled low by capacitor 34 which puts transistor 26 in a low conductance state. Transistor 26 however is not fully turned off. With this biasing of transistor 26, transistor 22, which is turned on by node 14 going low, can pull node 24 to a higher level in a faster amount of time than would otherwise be possible if transistors 26, 46 and 28 were influencing node 14.

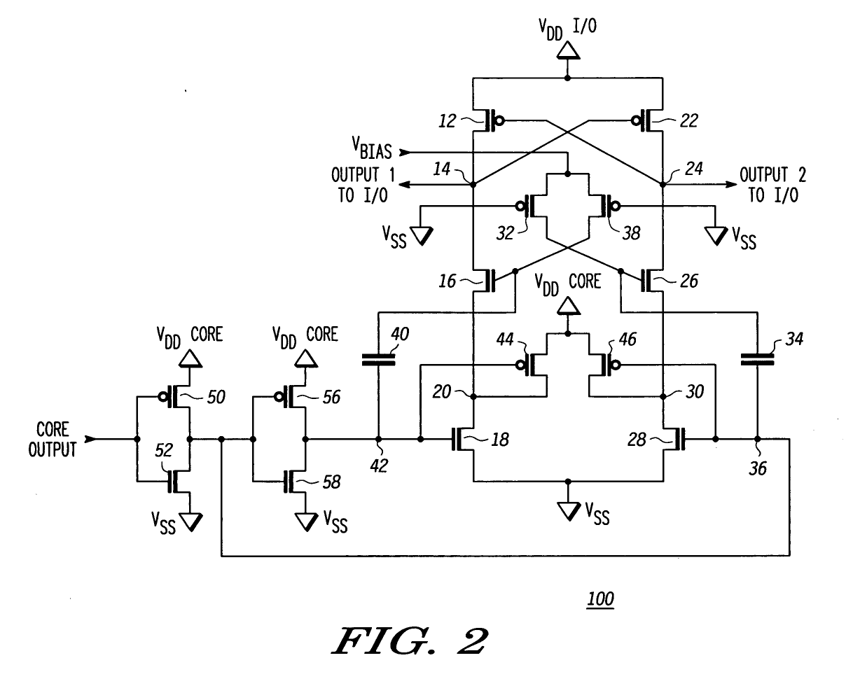

Illustrated in FIG. 2 is voltage level shifter 100 which is another form of the voltage level shifter of FIG. 1. For convenience of explanation, all similar elements between FIG. 2 and FIG. 1 are numbered with the same reference numbers. In the alternative form, the gate of transistor 32 is connected to a ground reference voltage terminal V_{SS}. Similarly, the gate of transistor 38 is connected to the ground reference voltage terminal V_{SS}. In this form, transistors 32 and 38 are fabricated to be weak devices meaning that the transistors are partially conductive. As a result, these transistors do not have to be turned on and turned off to isolate V_{BIAS} from the gates of transistors 16 and 26. Isolation between V_{BIAS} and the gates of transistors 16 and 26 allows capacitors 40 and 34 to modify the voltages on the gates of transistors 16 and 26 as a function of the logic values at nodes 42 and 36. Modifying the voltages on the gates of transistors 16 and 26 through the use of capacitors 40 and 34 allows faster rise times during input signal transitions and therefore speeds up circuit operation. The use of capacitors 40 and 34 assists significantly in making low-to-high voltage signal transitions at the two outputs to the I/O circuitry by providing a mechanism to quickly remove bias voltage from the gates of transistors 16 and 26.

By now it should be appreciated that there has been provided a level shifting circuit having improved control of duty cycle variation. The capacitors 40 and 34 assist in tightening the duty cycle variation of the level shifter. Capacitors 40 and 34 help couple charge onto the gates of transistors 16 and 26 which are connected in a cascode configuration with transistors 12 and 22, respectively. By using cascode configured transistors in each of voltage level shifter 10 and voltage level shifter 100, the speed is increased since the active P-channel transistor 44 and P-channel transistor 46 clamps function to precharge the total capacitance of nodes 20 and 30. Capacitors 40 and 34 therefore boost the bias voltage at the gate of transistors 16 and 26 above and below the bias voltage otherwise applied to these two transistors. The boosting above and below the bias voltage improves the rise and fall time matching of voltage level shifter 10 and voltage level shifter 100.

Various changes and modifications to the embodiments herein chosen for purposes of illustration will readily occur to those skilled in the art. For example, voltage level shifter 10 and voltage level shifter 100 may be implemented with various semiconductor technologies that are capable of implementing transistors of at least two different gate oxide thickness. The capacitors may be implemented with polysilicon-to-polysilicon capacitors, metal fringe capacitors and polysilicon-to-well capacitors as well as other types of capacitor structures. For example, polysilicon-to-well capacitors are transistor structures that are modified to function as a two terminal capacitive device. The conductivities of the transistors may be varied. Various voltages may be used in connection with the core voltages and the I/O voltages. Additionally, in some forms, transistors 32 and 38 of voltage level shifter 100 may be implemented as a resistor or other resistive device rather than as a transistor. In voltage level shifter 100 transistors 32 and 38 are not functioning as switches as they are in voltage level shifter 10, but in both implementations the transistors 32 and 38 are functioning as isolation devices to isolate V_{BIAS} from the gate of transistors 16 and 26. This provides a small signal discharge path from the gate capacitance of transistors 16 and 26 respectively through capacitors 40 and 34 rather than through the bias voltage which appears as an electrical short-circuit for small signals.

In one form there is provided a level shifting circuit for translating an input signal at a first voltage value up to a higher second voltage. A cross-coupled latch having two transistors is provided, each with a control electrode that is coupled to a current electrode of another of the two transistors. The cross-coupled latch is coupled to a high voltage supply terminal and has a first output for providing a first output at the higher second voltage and a second output for providing a second output at the higher second voltage. Two cascode configured transistors are provided, each of the two cascode configured transistors being respectively coupled in series with a respective different one of the two transistors of the cross-coupled latch. The two cascode configured transistors each have a control electrode coupled to a bias voltage terminal for receiving a predetermined bias voltage. Isolation devices are coupled between the bias voltage terminal and the control electrode of each of the two cascode configured transistors to provide small signal isolation between each control electrode of the two cascode configured transistors. Each of two input transistors is respectively coupled in series between a respective one of the two cascode configured transistors and a reference voltage terminal. The two input transistors receive the input signal in complementary form. A first capacitive device is coupled between the input signal and the control electrode of a first transistor of the two cascode configured transistors. The first capacitive device modifies charge at the control electrode of the first transistor in response to a change in state of the input signal. A second capacitive device is coupled between the input signal and the control electrode of a second transistor of the two cascode configured transistors. The second capacitive device modifies charge at the control electrode of the second transistor in response to a change in state of the input signal. Each of two clamp devices is coupled between a terminal for receiving the first voltage value and a respective one of current electrodes of the two input transistors. The two clamp devices selectively couple the first voltage value onto predetermined current electrodes of the two input transistors in response to the input signal to limit electrode voltage coupled to the predetermined current electrodes of the two input transistors to a maximum value. The two clamp devices also selectively precharge the predetermined current electrodes of the two input transistors to substantially the first voltage value. In one form the isolation devices are a first isolation transistor having a first current electrode coupled to the bias voltage terminal, a control electrode for receiving the input signal, and a second current electrode coupled to the control electrode of a first of the two cascode configured transistors, and a second isolation transistor. The second isolation transistor has a first current electrode coupled to the bias voltage terminal, a control electrode for receiving the input signal, and a second current electrode coupled to the control electrode of the first of the two cascode configured transistors. In another form the isolation devices includes a first isolation transistor having a first current electrode coupled to the bias voltage terminal, a control electrode coupled to the reference voltage terminal, and a second current electrode coupled to the control electrode of a first of the two cascode configured transistors, and a second isolation transistor. The second isolation transistor has a first current electrode coupled to the bias voltage terminal, a control electrode coupled to the reference voltage terminal, and a second current electrode coupled to the control electrode of the first of the two cascode configured transistors. The two transistors of the cross-coupled latch and the two cascode configured transistors each have a thicker gate oxide than the two input transistors for operating with the higher second voltage.

In another form there is provided a method for translating an input signal at a first voltage value up to a higher second voltage. The method includes receiving the input signal in complementary form at respective control electrodes of first and second transistors. Two cascode configured transistors are provided by coupling a third transistor in series with the first transistor and coupling a fourth transistor in series with the second transistor. The two cascode configured transistors limit voltage that is applied to the first and second transistors via coupling the third transistor and the fourth transistor. A fifth transistor is coupled in series with the third transistor and a sixth transistor is coupled in series with the fourth transistor. The fifth transistor and sixth transistor function as a cross-coupled latch wherein a control electrode of the fifth transistor is connected to a current electrode of the sixth transistor for providing a first output for providing the higher second voltage. A control electrode of the sixth transistor is connected to a current electrode of the fifth transistor for providing a second output for also providing the higher second voltage. A separate capacitive device is coupled to each control electrode of the two cascode configured transistors for modifying charge on each control electrode in response to the input signal. Resistance is placed between control electrodes of the two cascode configured transistors and a bias voltage terminal for receiving a bias voltage for the two cascode configured transistors. The resistance permits charge to be independently removed from each of the control electrodes of the two cascode configured transistors. Transistor current electrode voltage of the first and second transistors is limited to a predetermined maximum value in response to the input signal and current electrodes of the first and second transistors are precharged to substantially the first voltage value. In one form the gate oxide thickness of the first and second transistors is sized to be less than gate oxide thickness of the third transistor, the fourth transistor, the fifth transistor and the sixth transistor. In another form the resistance is implemented as separate transistors coupled between the control electrodes of the two cascode configured transistors and the bias voltage. In another form the separate transistors are switched in response to the input signal. In another form the separate transistors are maintained in a continuous state of at least partial conduction. In another form the first output and the second output are provided in complementary form and only one of the first output and the second output is used.

In yet another form there is provided a level shifter circuit for translating an input signal at a first voltage value up to a higher second voltage having a first transistor of a first conductivity type. The first transistor has a first current electrode coupled to a first voltage terminal, a control electrode for receiving the input signal, and a second current electrode. A second transistor of the first conductivity type has a first current electrode coupled to the first voltage terminal, a control electrode for receiving the input signal in an inverted form, and a second current electrode. A third transistor of the first conductivity type has a first current electrode coupled to the second current electrode of the first transistor, a control electrode, and a second current electrode. A fourth transistor of the first conductivity type has a first current electrode coupled to the second current electrode of the second transistor, a control electrode, and a second current electrode. A fifth transistor of a second conductivity type has a first current electrode coupled to the control electrode of the fourth transistor, a control electrode for receiving the input signal, and a second current electrode for receiving a bias voltage. A sixth transistor of the second conductivity type has a first current electrode coupled to the control electrode of the third transistor, a control electrode for receiving the input signal in an inverted form, and a second current electrode for receiving the bias voltage. A seventh transistor of the second conductivity type has a first current electrode coupled to the second current electrode of the third transistor, a control electrode coupled to the second current electrode of the fourth transistor, and a second current electrode coupled to a second voltage terminal. An eighth transistor of the second conductivity type has a first current electrode coupled to the second current electrode of the fourth transistor, a control electrode coupled to the second current electrode of the third transistor, and a second current electrode coupled to the second voltage terminal. A first capacitor has a first electrode coupled to the control electrode of the first transistor and has a second electrode coupled to the control electrode of the third transistor. A second capacitor has a first electrode coupled to the control electrode of the second transistor and has a second electrode coupled to the control electrode of the fourth transistor. A ninth transistor of the second conductivity type has a first current electrode coupled to the second current electrode of the first transistor, a control electrode coupled to the control electrode of the first transistor, and a second current electrode coupled to a third voltage terminal. A tenth transistor of the second conductivity type has a first current electrode coupled to the second current electrode of the second transistor, a control electrode coupled to the control electrode of the second transistor, and a second current electrode coupled to the third voltage terminal. In one form the second voltage terminal receives a first supply voltage potential that is greater in magnitude than a second supply voltage potential that the third voltage terminal receives by at least fifty percent of the first supply voltage potential. In another form the first transistor and the second transistor each have a gate oxide with a thickness that is less than gate oxide of each of the third transistor, the fourth transistor, the fifth transistor, the sixth transistor, the seventh transistor and the eighth transistor.

In another form there is provided a level shifter circuit for translating an input signal at a first voltage value up to a higher second voltage. A first transistor of a first conductivity type has a first current electrode coupled to a first voltage terminal, a control electrode for receiving the input signal, and a second current electrode. A second transistor of the first conductivity type has a first current electrode coupled to the first voltage terminal, a control electrode for receiving the input signal in an inverted form, and a second current electrode. A third transistor of the first conductivity type has a first current electrode coupled to the second current electrode of the first transistor, a control electrode, and a second current electrode. A fourth transistor of the first conductivity type has a first current electrode coupled to the second current electrode of the second transistor, a control electrode, and a second current electrode. A fifth transistor of a second conductivity type has a first current electrode coupled to the control electrode of the fourth transistor, a control electrode coupled to the first voltage terminal, and a second current electrode for receiving a bias voltage. A sixth transistor of the second conductivity type has a first current electrode coupled to the control electrode of the third transistor, a control electrode coupled to the first voltage terminal, and a second current electrode for receiving the bias voltage. A seventh transistor of the second conductivity type has a first current electrode coupled to the second current electrode of the third transistor, a control electrode coupled to the second current electrode of the fourth transistor, and a second current electrode coupled to a second voltage terminal. An eighth transistor of the second conductivity type has a first current electrode coupled to the second current electrode of the fourth transistor, a control electrode coupled to the second current electrode of the third transistor, and a second current electrode coupled to the second voltage terminal. A first capacitor has a first electrode coupled to the control electrode of the first transistor and a second electrode coupled to the control electrode of the third transistor. A second capacitor has a first electrode coupled to the control electrode of the second transistor and a second electrode coupled to the control electrode of the fourth transistor. In another form a ninth transistor of the second conductivity type has a first current electrode coupled to the second current electrode of the first transistor, a control electrode coupled to the control electrode of the first transistor, and a second current electrode coupled to a third voltage terminal. A tenth transistor of the second conductivity type has a first current electrode coupled to the second current electrode of the second transistor, a control electrode coupled to the control electrode of the second transistor, and a second current electrode coupled to the third voltage terminal. In one form the second voltage terminal receives a first supply voltage potential that is greater in magnitude than a second supply voltage potential that the third voltage terminal receives by at least fifty percent of the first supply voltage potential. In another form the first transistor and the second transistor each have a gate oxide with a thickness that is less than gate oxide of each of the third transistor, the fourth transistor, the fifth transistor, the sixth transistor, the seventh transistor and the eighth transistor.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms a or an, as used herein, are defined as one or more than one. The term plurality, as used herein, is defined as two or more than two. The term another, as used herein, is defined as at least a second or more. The terms including and/or having, as used herein, are defined as comprising (i.e., open language). The term coupled, as used herein, is defined as connected, although not necessarily directly, and not necessarily mechanically. To the extent that such modifications and variations do not depart from the spirit of the invention, they are intended to be included within the scope thereof which is assessed only by a fair interpretation of the following claims.

1. A level shifting circuit for translating an input signal at a first voltage value up to a higher second voltage, comprising:
a cross-coupled latch having two transistors each with a control electrode that is coupled to a current electrode of another of the two transistors, the cross-coupled latch being coupled to a high voltage supply terminal and having a first output for providing a first output at the higher second voltage and a second output for providing a second output at the higher second voltage;
two cascode configured transistors, each of the two cascode configured transistors being respectively coupled in series with a respective different one of the two transistors of the cross-coupled latch, the two cascode configured transistors each having a control electrode coupled to a bias voltage terminal for receiving a predetermined bias voltage;
isolation devices coupled between the bias voltage terminal and the control electrode of each of the two cascode configured transistors to provide small signal isolation between each control electrode of the two cascode configured transistors;
two input transistors, each of the two input transistors respectively coupled in series between a respective one of the two cascode configured transistors and a reference voltage terminal, the two input transistors receiving the input signal in complementary form;
a first capacitive device coupled between the input signal and the control electrode of a first transistor of the two cascode configured transistors, the first capacitive device modifying charge at the control electrode of the first transistor in response to a change in state of the input signal; and
a second capacitive device coupled between the input signal and the control electrode of a second transistor of the two cascode configured transistors, the second capacitive device modifying charge at the control electrode of the second transistor in response to a change in state of the input signal.

2. The level shifting circuit of claim 1 further comprising:
two clamp devices, each of the two clamp devices being coupled between a terminal for receiving the first voltage value and a respective one of current electrodes of the two input transistors, the two clamp devices selectively coupling the first voltage value onto predetermined current electrodes of the two input transistors in response to the input signal to limit electrode voltage coupled to the predetermined current electrodes of the two input transistors to a maximum value and to selectively precharge the predetermined current electrodes of the two input transistors to substantially the first voltage value.

3. The level shifting circuit of claim 1 wherein the isolation devices further comprise:
a first isolation transistor having a first current electrode coupled to the bias voltage terminal, a control electrode for receiving the input signal, and a second current electrode coupled to the control electrode of a first of the two cascode configured transistors; and
a second isolation transistor having a first current electrode coupled to the bias voltage terminal, a control electrode for receiving the input signal, and a second current electrode coupled to the control electrode of the second of the two cascode configured transistors.

4. The level shifting circuit of claim 1 wherein the isolation devices further comprise:
a first isolation transistor having a first current electrode coupled to the bias voltage terminal, a control electrode coupled to the reference voltage terminal, and a second current electrode coupled to the control electrode of a first of the two cascode configured transistors; and
a second isolation transistor having a first current electrode coupled to the bias voltage terminal, a control electrode coupled to the reference voltage terminal, and a second current electrode coupled to the control electrode of the second of the two cascode configured transistors

5. The level shifting circuit of claim 1 wherein the two transistors of the cross-coupled latch and the two cascode configured transistors each have a thicker gate oxide than the two input transistors for operating with the higher second voltage.

6. A method for translating an input signal at a first voltage value up to a higher second voltage, comprising:
receiving the input signal in complementary form at respective control electrodes of first and second transistors;
providing two cascode configured transistors by coupling a third transistor in series with the first transistor and coupling a fourth transistor in series with the second transistor, the two cascode configured transistors limiting voltage that is applied to the first and second transistors via coupling the third transistor and the fourth transistor;
coupling a fifth transistor in series with the third transistor and coupling a sixth transistor in series with the fourth transistor, the fifth transistor and sixth transistor functioning as a cross-coupled latch wherein a control electrode of the fifth transistor is connected to a current electrode of the sixth transistor for providing a first output for providing the higher second voltage, and a control electrode of the sixth transistor is connected to a current electrode of the fifth transistor for providing a second output for also providing the higher second voltage;
coupling a separate capacitive device to each control electrode of the two cascode configured transistors for modifying charge on each control electrode in response to the input signal; and
placing resistance between control electrodes of the two cascode configured transistors and a bias voltage terminal for receiving a bias voltage for the two cascode configured transistors, the resistance permitting charge to be independently removed from each of the control electrodes of the two cascode configured transistors.

7. The method of claim 6 further comprising:
further limiting current electrode voltage of the first and second transistors to a predetermined maximum value in response to the input signal and precharging current electrodes of the first and second transistors to substantially the first voltage value.

8. The method of claim 6 further comprising:
sizing gate oxide thickness of the first and second transistors to be less than gate oxide thickness of the third transistor, the fourth transistor, the fifth transistor and the sixth transistor.

9. The method of claim 6 further comprising:
implementing the resistance as separate transistors coupled between the control electrodes of the two cascode configured transistors and the bias voltage.

10. The method of claim 9 further comprising:
switching the separate transistors in response to the input signal.

11. The method of claim 9 further comprising:
maintaining the separate transistors in a continuous state of at least partial conduction.

12. The method of claim 6 further comprising:
providing the first output and the second output in complementary form and using only one of the first output and the second output.

13. A level shifter circuit for translating an input signal at a first voltage value up to a higher second voltage, comprising:
a first transistor of a first conductivity type having a first current electrode coupled to a first voltage terminal, a control electrode for receiving the input signal, and a second current electrode; a second transistor of the first conductivity type having a first current electrode
coupled to the first voltage terminal, a control electrode for receiving the input signal in an inverted form, and a second current electrode;
a third transistor of the first conductivity type having a first current electrode coupled to the second current electrode of the first transistor, a control electrode, and a second current electrode;
a fourth transistor of the first conductivity type having a first current electrode coupled to the second current electrode of the second transistor, a control electrode, and a second current electrode;
a fifth transistor of a second conductivity type having a first current electrode coupled to the control electrode of the fourth transistor, a control electrode for receiving the input signal, and a second current electrode for receiving a bias voltage;
a sixth transistor of the second conductivity type having a first current electrode coupled to the control electrode of the third transistor, a control electrode for receiving the input signal in an inverted form, and a second current electrode for receiving the bias voltage;
a seventh transistor of the second conductivity type having a first current electrode coupled to the second current electrode of the third transistor, a control electrode coupled to the second current electrode of the fourth transistor, and a second current electrode coupled to a second voltage terminal;
an eighth transistor of the second conductivity type having a first current electrode coupled to the second current electrode of the fourth transistor, a control electrode coupled to the second current electrode of the third transistor, and a second current electrode coupled to the second voltage terminal;
a first capacitor having a first electrode coupled to the control electrode of the first transistor and having a second electrode coupled to the control electrode of the third transistor; and
a second capacitor having a first electrode coupled to the control electrode of the second transistor and having a second electrode coupled to the control electrode of the fourth transistor.

14. The level shifter circuit of claim 13 further comprising:
a ninth transistor of the second conductivity type having a first current electrode coupled to the second current electrode of the first transistor, a control electrode coupled to the control electrode of the first transistor, and a second current electrode coupled to a third voltage terminal; and
a tenth transistor of the second conductivity type having a first current electrode coupled to the second current electrode of the second transistor, a control electrode coupled to the control electrode of the second transistor, and a second current electrode coupled to the third voltage terminal.

15. The level shifter circuit of claim 14 wherein the second voltage terminal receives a first supply voltage potential that is greater in magnitude than a second supply voltage potential that the third voltage terminal receives by at least fifty percent of the first supply voltage potential.

16. The level shifter circuit of claim 13 wherein the first transistor and the second transistor each have a gate oxide with a thickness that is less than gate oxide of each of the third transistor, the fourth transistor, the fifth transistor, the sixth transistor, the seventh transistor and the eighth transistor.

17. A level shifter circuit for translating an input signal at a first voltage value up to a higher second voltage, comprising:
a first transistor of a first conductivity type having a first current electrode coupled to a first voltage terminal, a control electrode for receiving the input signal, and a second current electrode;
a second transistor of the first conductivity type having a first current electrode coupled to the first voltage terminal, a control electrode for receiving the input signal in an inverted form, and a second current electrode;
a third transistor of the first conductivity type having a first current electrode coupled to the second current electrode of the first transistor, a control electrode, and a second current electrode;
a fourth transistor of the first conductivity type having a first current electrode coupled to the second current electrode of the second transistor, a control electrode, and a second current electrode;
a fifth transistor of a second conductivity type having a first current electrode coupled to the control electrode of the fourth transistor, a control electrode coupled to the first voltage terminal, and a second current electrode for receiving a bias voltage;
a sixth transistor of the second conductivity type having a first current electrode coupled to the control electrode of the third transistor, a control electrode coupled to the first voltage terminal, and a second current electrode for receiving the bias voltage;
a seventh transistor of the second conductivity type having a first current electrode coupled to the second current electrode of the third transistor, a control electrode coupled to the second current electrode of the fourth transistor, and a second current electrode coupled to a second voltage terminal;
an eighth transistor of the second conductivity type having a first current electrode coupled to the second current electrode of the fourth transistor, a control electrode coupled to the second current electrode of the third transistor, and a second current electrode coupled to the second voltage terminal;
a first capacitor having a first electrode coupled to the control electrode of the first transistor and having a second electrode coupled to the control electrode of the third transistor; and
a second capacitor having a first electrode coupled to the control electrode of the second transistor and having a second electrode coupled to the control electrode of the fourth transistor.

18. The level shifter circuit of claim 17 further comprising:
a ninth transistor of the second conductivity type having a first current electrode coupled to the second current electrode of the first transistor, a control electrode coupled to the control electrode of the first transistor, and a second current electrode coupled to a third voltage terminal; and
a tenth transistor of the second conductivity type having a first current electrode coupled to the second current electrode of the second transistor, a control electrode coupled to the control electrode of the second transistor, and a second current electrode coupled to the third voltage terminal.

19. The level shifter circuit of claim 18 wherein the second voltage terminal receives a first supply voltage potential that is greater in magnitude than a second supply voltage potential that the third voltage terminal receives by at least fifty percent of the first supply voltage potential.

20. The level shifter circuit of claim 17 wherein the first transistor and the second transistor each have a gate oxide with a thickness that is less than gate oxide of each of the third transistor, the fourth transistor, the fifth transistor, the sixth transistor, the seventh transistor and the eighth transistor.
